(19) United States
(12) Patent Application Publication
(10) Pub. No.: US 2025/0194394 A1
(43) Pub. Date: Jun. 12, 2025

(54) DISPLAY DEVICE AND METHOD OF MANUFACTURING THE SAME

(71) Applicant: Samsung Display Co., LTD., Yongin-si (KR)

(72) Inventors: Jae Been LEE, Yongin-si (KR); Ye Hwan CHOI, Yongin-si (KR); Ju Won YOON, Yongin-si (KR)

(21) Appl. No.: 18/954,279

(22) Filed: Nov. 20, 2024

(30) Foreign Application Priority Data
Dec. 6, 2023 (KR) 10-2023-0175262

(51) Int. Cl. H10K 71/00; H10K 59/12; H10K 59/80

(52) U.S. Cl. CPC H10K 71/621; H10K 59/1201; H10K 59/8051

(57) ABSTRACT

In a method of manufacturing a display device, the method includes: providing a substrate; forming an anode electrode on the substrate; forming a first insulating layer on the anode electrode; forming a trench by etching the first insulating layer; forming a second insulating layer on the first insulating layer through a process different from that of the first insulating layer; exposing at least a portion of the first insulating layer overlapping the anode electrode by etching the second insulating layer; and exposing the anode electrode by concurrently etching the at least the portion of the first insulating layer and the second insulating layer.

The present application claims priority to and the benefit of Korean Patent Application No. 10-2023-0175262, filed on Dec. 6, 2023, in the Korean Intellectual Property Office, the entire disclosure of which is incorporated herein by reference.

### BACKGROUND

### 1. Field

Aspects of some embodiments of the present disclosure relate to a display device and a method of manufacturing the display device.

### 2. Description of the Related Art

As information technology develops, the importance of display devices, which provide a connection medium between users and information, is growing. In response to this, a use of a display device such as a liquid crystal display device and an organic light emitting display device is increasing.

Recently, head mounted display devices (HMDs) are being developed. HMDs are display devices that implement virtual reality (VR) or augmented reality (AR) in which a user wears the HMD in a form of glasses or a helmet and a focus is formed at a distance close to eyes. A high-resolution panel may be applied to the HMD, and thus a pixel that may be applied to the high-resolution panel may be utilized.

The above information disclosed in this Background section is only for enhancement of understanding of the background and therefore the information discussed in this Background section does not necessarily constitute prior art.

### SUMMARY

Aspects of some embodiments of the present disclosure relate to a display device and a method of manufacturing the display device. For example, aspects of some embodiments of the present disclosure relate to a display device including a trench and a method of manufacturing the display device.

Aspects of some embodiments of the present disclosure include a method of manufacturing a display device using a second pixel defining layer as a mask of a first pixel defining layer.

Aspects of some embodiments of the present disclosure include a display device produced by using a second pixel defining layer as a mask of a first pixel defining layer.

According to some embodiments of the present disclosure, in a method of manufacturing a display device, the method includes: providing a substrate, forming an anode electrode on the substrate, forming a first insulating layer on the anode electrode, forming a trench by etching the first insulating layer, forming a second insulating layer on the first insulating layer through a process different from that of the first insulating layer, exposing at least a portion of the first insulating layer overlapping the anode electrode by etching the second insulating layer, and exposing the anode electrode by simultaneously etching the at least the portion of the first insulating layer and the second insulating layer.

According to some embodiments, in exposing the anode electrode, an etch speed of the second insulating layer may be slower than an etch speed of the at least the portion of the first insulating layer.

According to some embodiments, the first insulating layer may be formed in a chemical vapor deposition (CVD) method.

According to some embodiments, the second insulating layer may be formed in an atomic layer deposition (ALD) method.

According to some embodiments, after the anode electrode is exposed, a thickness of the second insulating layer formed on an upper surface of the first insulating layer may be thinner than a thickness of the second insulating layer formed on a side surface of the first insulating layer.

According to some embodiments, a thickness at which the second insulating layer is formed may be determined according to a width of the trench.

According to some embodiments, in exposing the anode electrode, the at least the portion of the first insulating layer and the second insulating layer may be etched through an etch back process.

According to some embodiments of the present disclosure, in a method of manufacturing a display device, the method includes: providing a substrate, forming an anode electrode on the substrate, forming a first insulating layer on the anode electrode, forming a trench by etching the first insulating layer, forming a second insulating layer including a material different from that of the first insulating layer on the first insulating layer, exposing at least a portion of the first insulating layer overlapping the anode electrode by etching the second insulating layer, and exposing the anode electrode by simultaneously etching the at least the portion of the first insulating layer and the second insulating layer.

According to some embodiments, in exposing the anode electrode, an etch speed of the second insulating layer may be slower than an etch speed of the at least the portion of the first insulating layer.

According to some embodiments, the first insulating layer may include silicon oxide.

According to some embodiments, the second insulating layer may include silicon nitride.

According to some embodiments, after the anode electrode is exposed, a thickness of the second insulating layer formed on an upper surface of the first insulating layer may be thinner than a thickness of the second insulating layer formed on a side surface of the first insulating layer.

According to some embodiments, a thickness at which the second insulating layer is formed may be determined according to a width of the trench.

According to some embodiments, in exposing the anode electrode, the at least the portion of the first insulating layer and the second insulating layer may be etched through an etch back process.

According to some embodiments of the present disclosure, in a method of manufacturing a display device, the method includes: providing a substrate, forming an anode electrode on the substrate, forming a first insulating layer on the anode electrode, forming a trench by etching the first insulating layer, forming a second insulating layer on the first insulating layer, exposing at least a portion of the first insulating layer overlapping the anode electrode by etching the second insulating layer, and exposing the anode electrode by etching the at least the portion of the first insulating layer.

According to some embodiments, in exposing the anode electrode, the at least the portion of the first insulating layer may be etched through wet etching.

According to some embodiments, an etch speed of the first insulating layer by an etching solution of the wet etching may be faster than that of the second insulating layer.

According to some embodiments, the first insulating layer may include silicon oxide, the second insulating layer may include silicon nitride, and an etching solution of the wet etching may include a buffered oxide etchant (BOE) solution.

According to some embodiments, the first insulating layer may include silicon oxide, the second insulating layer may include silicon nitride, and the etching solution of the wet etching may include a tetramethyl ammonium hydroxide (TMAH) solution.

According to some embodiments, the first insulating layer may be silicon nitride, the second insulating layer may be silicon oxide, and the etching solution of the wet etching may include phosphoric acid.

According to some embodiments of the present disclosure, a display device may include: a substrate, an anode electrode formed on the substrate, a first insulating layer formed on the anode electrode, a second insulating layer formed on the first insulating layer, a light emitting structure located on the anode electrode exposed by openings of the first insulating layer and the second insulating layer, and a cathode electrode located on the light emitting structure, and a difference between a thickness of a second insulating layer formed on a side surface of a first insulating layer and a thickness of the second insulating layer formed on an upper surface of the first insulating layer may be less than a thickness of the first pixel defining layer.

A method of manufacturing a display device according to some embodiments of the disclosure may relatively simplify a manufacturing process by using the second pixel defining layer as a mask of the first pixel defining layer.

However, the characteristics of embodiments according to the present disclosure are not limited to the characteristics described above, and may be variously expanded without departing from the spirit and scope of embodiments according to the present disclosure.

### BRIEF DESCRIPTION OF THE DRAWINGS

The above and other characteristics of embodiments according to the present disclosure will become more apparent by describing in further detail aspects of some embodiments thereof with reference to the accompanying drawings, in which:

FIG. 1 is a block diagram illustrating aspects of a display device according to some embodiments;

FIG. 2 is a block diagram illustrating aspects of a sub-pixel of FIG. 1 according to some embodiments;

FIG. 3 is a plan view illustrating aspects of a display panel of FIG. 1 according to some embodiments;

FIG. 4 is an exploded perspective view illustrating a portion of the display panel of FIG. 3 according to some embodiments;

FIG. 5 is a plan view illustrating aspects of a pixel of FIG. 4 according to some embodiments;

FIG. 6 is a cross-sectional view taken along a line I-I′ of FIG. 5;

FIG. 7 is a flowchart illustrating a method of manufacturing a display device according to some embodiments of the disclosure;

FIG. 8 is a diagram illustrating an example of operation S200 of FIG. 7;

FIG. 9 is a diagram illustrating an example of operation S300 of FIG. 7;

FIG. 10 is a diagram illustrating an example of operation S400 of FIG. 7;

FIG. 11 is a diagram illustrating an example of operation S500 of FIG. 7;

FIG. 12 is a diagram illustrating an example of operation S600 of FIG. 7;

FIG. 13 is a diagram illustrating an example of operation S710 of FIG. 7;

FIG. 14 is a flowchart illustrating a method of manufacturing a display device according to some embodiments of the disclosure;

FIG. 15 is a diagram illustrating an example of operation S720 of FIG. 14;

FIG. 16 is a block diagram illustrating aspects of a display system according to some embodiments;

FIG. 17 is a perspective view illustrating an application example of the display system of FIG. 16 according to some embodiments; and

FIG. 18 is a diagram illustrating a head mounted display device worn by a user of FIG. 17 according to some embodiments.

### DETAILED DESCRIPTION

Hereinafter, aspects of some embodiments of the present disclosure are described in more detail with reference to the accompanying drawings. It should be noted that in the following description, only portions necessary for understanding an operation according to the disclosure are described, and descriptions of other portions are omitted in order not to obscure the subject matter of the disclosure. In addition, the disclosure may be embodied in other forms without being limited to the embodiments described herein. However, the embodiments described herein are provided to describe in detail enough to easily implement the technical spirit of the disclosure to those skilled in the art to which the disclosure belongs.

Throughout the specification, in a case where a portion is “connected” to another portion, the case includes not only a case where the portion is “directly connected” but also a case where the portion is “indirectly connected” with another element interposed therebetween. Terms used herein are for describing specific embodiments and are not intended to limit the disclosure. Throughout the specification, in a case where a certain portion “includes”, the case means that the portion may further include another component without excluding another component unless otherwise stated. “At least any one of X, Y, and Z” and “at least any one selected from a group consisting of X, Y, and Z” may be interpreted as one X, one Y, one Z, or any combination of two or more of X, Y, and Z (for example, XYZ, XYY, YZ, and ZZ). Here, “and/or” includes all combinations of one or more of corresponding configurations.

Here, terms such as first and second may be used to describe various components, but these components are not limited to these terms. These terms are used to distinguish one component from another component. Therefore, a first component may refer to a second component within a range without departing from the scope disclosed herein.

Spatially relative terms such as “under”, “on”, and the like may be used for descriptive purposes, thereby describing a relationship between one element or feature and another element(s) or feature(s) as shown in the drawings. Spatially relative terms are intended to include other directions in use, in operation, and/or in manufacturing, in addition to the direction depicted in the drawings. For example, when a device shown in the drawing is turned upside down, elements depicted as being positioned “under” other elements or features are positioned in a direction “on” the other elements or features. Therefore, in the present disclosure, the term “under” may include both directions of on and under. In addition, the device may face in other directions (for example, rotated 90 degrees or in other directions) and thus the spatially relative terms used herein are interpreted according thereto.

Aspects of some embodiments according to the present disclosure are described more fully with reference to drawings schematically illustrating ideal embodiments. Accordingly, it will be expected that shapes may vary, for example, according to tolerances and/or manufacturing techniques. Therefore, the embodiments disclosed herein cannot be construed as being limited to shown specific shapes, and should be interpreted as including, for example, changes in shapes that occur as a result of manufacturing. As described above, the shapes shown in the drawings may not show actual shapes of areas of a device, and embodiments according to the present disclosure are not limited thereto.

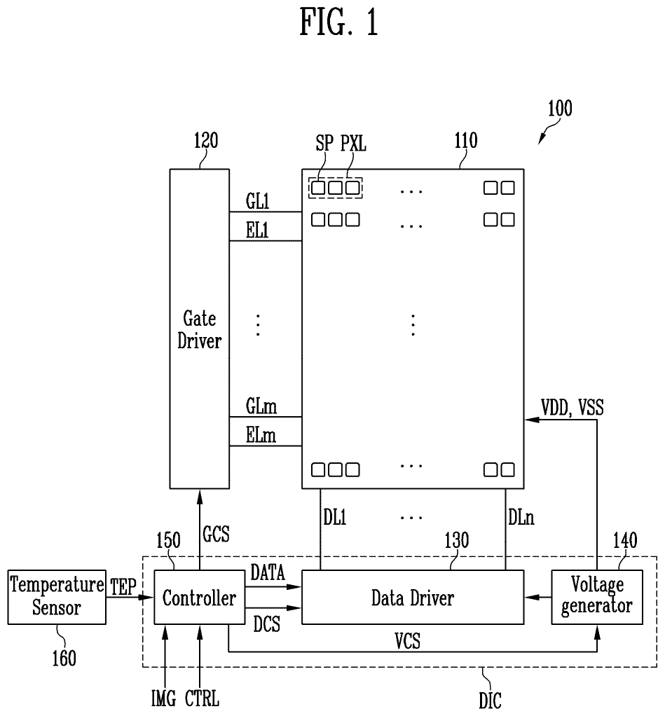

FIG. 1 is a diagram illustrating aspects of a display device according to some embodiments.

Referring to FIG. 1, the display device 100 may include a display panel 110, a gate driver 120, a data driver 130, a voltage generator 140, and a controller 150.

The display panel 110 includes sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

Each of the sub-pixels SP may include at least one light emitting element configured to generate light. Accordingly, each of the sub-pixels SP may generate light of a specific color such as red, green, blue, cyan, magenta, or yellow. Two or more sub-pixels among the sub-pixels SP may configure one pixel PXL. For example, as shown in FIG. 1, three sub-pixels may configure one pixel PXL.

The gate driver 120 is connected to the sub-pixels SP arranged in a row direction through the first to m-th gate lines GL1 to GLm. The gate driver 120 may output gate signals to the first to m-th gate lines GL1 to GLm in response to a gate control signal GCS. According to some embodiments, the gate control signal GCS may include a start signal indicating a start of each frame, a horizontal synchronization signal for outputting the gate signals in synchronization with a timing at which data signals are applied, and the like.

According to some embodiments, first to m-th emission control lines EL1 to ELm connected to the sub-pixels SP of the row direction may be further provided. In this case, the gate driver 120 may include an emission control driver configured to control the first to m-th emission control lines EL1 to ELm, and the emission control driver may operate under control of the controller 150.

The gate driver 120 may be located on one side of the display panel 110. However, embodiments according to the present disclosure are not limited thereto. For example, the gate driver 120 may be divided into two or more physically and/or logically divided drivers, and such drivers may be located on one side of the display panel 110 and another side of the display panel 110 opposite the one side. As described above, the gate driver 120 may be arranged around the display panel 110 in various shapes according to some embodiments.

The data driver 130 is connected to the sub-pixels SP arranged in a column direction through the first to n-th data lines DL1 to DLn. The data driver 130 receives image data DATA and a data control signal DCS from the controller 150. The data driver 130 operates in response to the data control signal DCS. According to some embodiments, the data control signal DCS may include a source start pulse, a source shift clock, a source output enable signal, and the like.

The data driver 130 may apply data signals having grayscale voltages corresponding to the image data DATA to the first to n-th data lines DL1 to DLn using voltages from the voltage generator 140. When the gate signal is applied to each of the first to m-th gate lines GL1 to GLm, the data signals corresponding to the image data DATA may be applied to the first to n-th data lines DL1 to DLn. Accordingly, the corresponding sub-pixels SP may generate light corresponding to the data signals. Accordingly, images may be displayed on the display panel 110.

According to some embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 is configured to generate a plurality of voltages and provide the generated voltages to components of the display device 100. For example, the voltage generator 140 may be configured to generate the plurality of voltages by receiving an input voltage from an outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level lower than that of the first power voltage VDD. According to some embodiments, the first power voltage VDD or the second power voltage VSS may be provided by an external device of the display device 100.

In addition, the voltage generator 140 may generate various voltages. For example, the voltage generator 140 may generate an initialization voltage applied to the sub-pixels SP. For example, during a sensing operation for sensing electrical characteristics of transistors and/or light emitting elements of the sub-pixels SP, a reference voltage (e.g., a set or predetermined reference voltage) may be applied to the first to n-th data lines DL1 to DLn, and the voltage generator 140 may generate such a reference voltage.

The controller 150 controls overall operations of the display device 100. The controller 150 receives input image data IMG and a control signal CTRL for controlling display of the input image data IMG from the outside. The controller 150 may provide the gate control signal GCS, the data control signal DCS, and the voltage control signal VCS in response to the control signal CTRL.

The controller 150 may convert the input image data IMG so that the input image data IMG is suitable for the display device 100 or the display panel 110 and output the image data DATA. According to some embodiments, the controller 150 may output the image data DATA by aligning the input image data IMG so that the input image data IMG is suitable for the sub-pixels SP of a row unit.

Two or more components of the data driver 130, the voltage generator 140, and the controller 150 may be mounted on one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally divided components in one driver integrated circuit DIC. According to some embodiments, at least one of the data driver 130, the voltage generator 140, or the controller 150 may be provided as a component distinguished from the driver integrated circuit DIC.

The display device 100 may include at least one temperature sensor 160. The temperature sensor 160 is configured to sense a temperature around the temperature sensor 160 and generate temperature data TEP indicating the sensed temperature. According to some embodiments, the temperature sensor 160 may be located adjacent to the display panel 110 and/or the driver integrated circuit DIC.

The controller 150 may control various operations of the display device 100 in response to the temperature data TEP. According to some embodiments, the controller 150 may adjust a luminance of the image output from the display panel 110 in response to the temperature data TEP. For example, the controller 150 may control the data signals and the first and second power voltages VDD and VSS by controlling components such as the data driver 130 and/or the voltage generator 140.

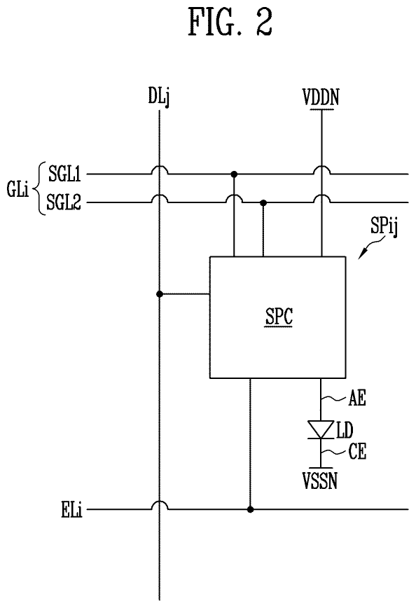

FIG. 2 is a block diagram illustrating an example of any one of the sub-pixels of FIG. 1. In FIG. 2, among the sub-pixels SP of FIG. 1, a sub-pixel SPij arranged in an i-th row (I is an integer greater than or equal to 1 and less than or equal to m) and a j-th column (j is an integer greater than or equal to 1 and less than or equal to n) is shown as an example.

Referring to FIG. 2, the sub-pixel SPij may include a sub-pixel circuit SPC and a light emitting element LD.

The light emitting element LD is connected between a first power voltage node VDDN and a second power voltage node VSSN. At this time, the first power voltage node VDDN is a node that transfers the first power voltage VDD of FIG. 1, and the second power voltage node VSSN is a node that transfers the second power voltage VSS of FIG. 1.

An anode electrode AE of the light emitting element LD may be connected to the first power voltage node VDDN through the sub-pixel circuit SPC, and a cathode electrode CE of the light emitting element LD may be connected to the second power voltage node VSSN. For example, the anode electrode AE of the light emitting element LD may be connected to the first power voltage node VDDN through one or more transistors included in the sub-pixel circuit SPC.

The sub-pixel circuit SPC may be connected to an i-th gate line GLi among the first to m-th gate lines GL1 to GLm of FIG. 1, an i-th emission control line ELi among the first to m-th emission control lines EL1 to eLm of FIG. 1, and a j-th data line DLj among the first to n-th data lines DL1 to DLn of FIG. 1. The sub-pixel circuit SPC is configured to control the light emitting element LD according to signals received through such signal lines.

The sub-pixel circuit SPC may operate in response to a gate signal received through the i-th gate line GLi. The i-th gate line GLi may include one or more sub-gate lines. According to some embodiments, as shown in FIG. 2, the i-th gate line GLi may include first and second sub-gate lines SGL1 and SGL2. The sub-pixel circuit SPC may operate in response to gate signals received through the first and second sub-gate lines SGL1 and SGL2. As described above, when the i-th gate line GLi includes two or more sub-gate lines, the sub-pixel circuit SPC may operate in response to gate signals received through the corresponding sub-gate lines.

The sub-pixel circuit SPC may operate in response to an emission control signal received through the i-th emission control line ELi. According to some embodiments, the i-th emission control line ELi may include one or more sub-emission control lines. When the i-th emission control line ELi includes two or more sub-emission control lines, the sub-pixel circuit SPC may operate in response to emission control signals received through the corresponding sub-emission control lines.

The sub-pixel circuit SPC may receive a data signal through the j-th data line DLj. The sub-pixel circuit SPC may store a voltage corresponding to the data signal in response to at least one of the gate signals received through the first or second sub-gate lines SGL1 or SGL2. The sub-pixel circuit SPC may adjust a current flowing from the first power voltage node VDDN to the second power voltage node VSSN through the light emitting element LD according to the stored voltage, in response to the emission control signal received through the i-th emission control line ELi. Accordingly, the light emitting element LD may generate light of a luminance corresponding to the data signal.

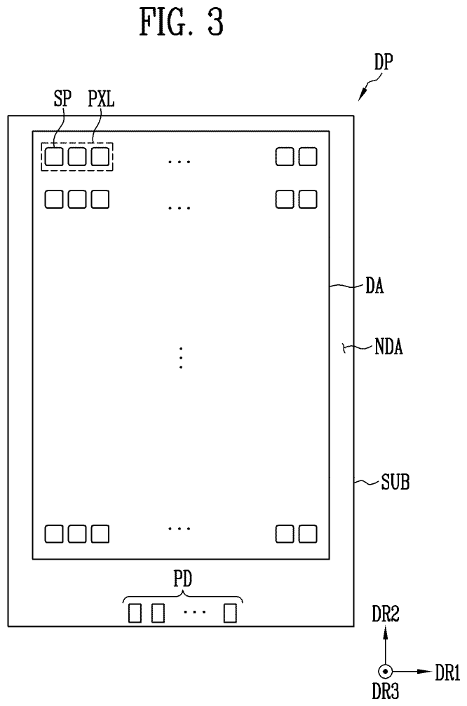

FIG. 3 is a plan view illustrating aspects of the display panel of FIG. 1 according to some embodiments.

Referring to FIG. 3, a display panel DP, as an example of the display panel 110 of FIG. 1, may include a display area DA and a non-display area NDA. The display panel DP displays images through or at the display area DA. The non-display area NDA is arranged around (e.g., in a periphery or outside a footprint of) the display area DA.

The display panel DP may include a substrate SUB, the sub-pixels SP, and pads PD.

When the display panel DP is used as a display screen of a head mounted display (HMD), a virtual reality (VR) device, a mixed reality (MR) device, an augmented reality (AR) device, or the like, the display panel DP may be positioned very close to user's eyes. In this case, sub-pixels SP of a relatively high integration degree are required. In order to increase an integration degree of the sub-pixels SP, the substrate SUB may be provided as a silicon substrate. The sub-pixels SP and/or the display panel DP may be formed on the substrate SUB, which is the silicon substrate. The display device 100 (refer to FIG. 1) including the display panel DP formed on the substrate SUB, which is the silicon substrate, may be referred to as an OLED on silicon (OLEDoS) display device.

The sub-pixels SP are located in the display area DA on the substrate SUB. The sub-pixels SP may be arranged in a matrix shape along a first direction DR1 and a second direction DR2 crossing the first direction DR1. However, embodiments according to the present disclosure are not limited thereto. For example, the sub-pixels SP may be arranged in a zigzag shape along the first direction DR1 and the second direction DR2. For example, the sub-pixels SP may be arranged in a PENTILE™ shape (for example, a diamond PENTILE™ shape). The first direction DR1 may be a row direction, and the second direction DR2 may be a column direction.

Two or more sub-pixels among the plurality of sub-pixels SP may configure one pixel PXL.

A component for controlling the sub-pixels SP may be located in the non-display area NDA on the substrate SUB. For example, lines connected to the sub-pixels SP, such as the first to m-th gate lines GL1 to GLm and the first to n-th data lines DL1 to DLn of FIG. 1, may be located in the non-display area NDA.

At least one of the gate driver 120, the data driver 130, the voltage generator 140, the controller 150, or the temperature sensor 160 of FIG. 1 may be integrated in the non-display area NDA of the display panel DP. According to some embodiments, the gate driver 120 of FIG. 1 may be mounted on the display panel DP and may be located in the non-display area NDA. According to some embodiments, the gate driver 120 may be implemented as an integrated circuit separated from the display panel DP. According to some embodiments, the temperature sensor 160 may be located in the non-display area NDA to sense a temperature of the display panel DP.

The pads PD are located in the non-display area NDA on the substrate SUB. The pads PD may be electrically connected to the sub-pixels SP through lines. For example, the pads PD may be connected to the sub-pixels SP through the first to n-th data lines DL1 to DLn.

The pads PD may interface the display panel DP to other components of the display device 100 (refer to FIG. 1). According to some embodiments, voltages and signals necessary for an operation of components included in the display panel DP may be provided from the driver integrated circuit DIC of FIG. 1 through the pads PD. For example, the first to n-th data lines DL1 to DLn may be connected to the driver integrated circuit DIC through the pads PD. For example, the first and second power voltages VDD and VSS may be received from the driver integrated circuit DIC through the pads PD. For example, when the gate driver 120 is mounted on the display panel DP, the gate control signal GCS may be transmitted from the driver integrated circuit DIC to the gate driver 120 through the pads PD.

According to some embodiments, a circuit board may be electrically connected to the pads PD using a conductive adhesive member such as an anisotropic conductive film. At this time, the circuit board may be a flexible print circuit board (FPCB) or a flexible film having a flexible material. The driver integrated circuit DIC may be mounted on the circuit board to be electrically connected to the pads PD.

According to some embodiments, the display area DA may have various shapes. The display area DA may have a closed loop shape including straight and/or curved sides. For example, the display area DA may have shapes such as a polygon, a circle, a semicircle, and an ellipse.

According to some embodiments, the display panel DP may have a flat display surface. According to some embodiments, the display panel DP may have a display surface that is at least partially round. According to some embodiments, the display panel DP may be bendable, foldable, or rollable. In these cases, the display panel DP and/or the substrate SUB may include materials having a flexible property.

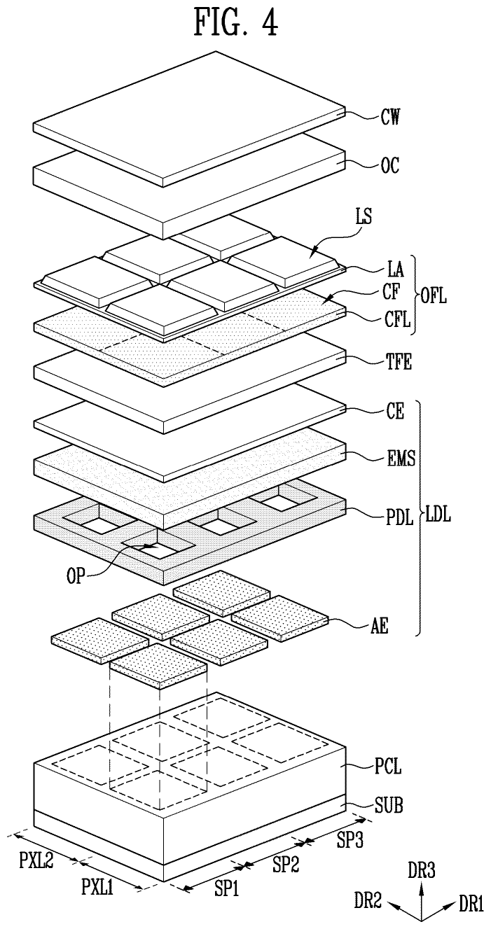

FIG. 4 is an exploded perspective view illustrating a portion of the display panel of FIG. 3. In FIG. 4, for clear and concise description, a portion of the display panel DP corresponding to two pixels PXL1 and PXL2 among the pixels PXL of FIG. 3 is schematically shown. A portion of the display panel DP corresponding to remaining pixels may be similarly configured.

Referring to FIGS. 3 and 4, each of the first and second pixels PXL1 and PXL2 may include first to third sub-pixels SP1, SP2, and SP3. However, embodiments according to the present disclosure are not limited thereto. For example, each of the first and second pixels PXL1 and PXL2 may include four sub-pixels or two sub-pixels.

In FIG. 4, the first to third sub-pixels SP1, SP2, and SP3 have quadrangle shapes when viewed from a third direction DR3 crossing the first and second directions DR1 and DR2 (e.g., in a plan view), and have sizes equal to each other. However, embodiments according to the present disclosure are not limited thereto. The first to third sub-pixels SP1, SP2, and SP3 may be modified to have various shapes (e.g., circular, oval, elliptical, or any other suitable shape in a plan view).

The display panel DP may include the substrate SUB, a pixel circuit layer PCL, a light emitting element layer LDL, an encapsulation layer TFE, an optical functional layer OFL, an overcoat layer OC, and a cover window CW.

According to some embodiments, the substrate SUB may include a silicon wafer substrate formed using a semiconductor manufacturing process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOI) layer, or the like. According to some embodiments, the substrate SUB may include a glass substrate. According to some embodiments, the substrate SUB may include a polyimide (PI) substrate.

The pixel circuit layer PCL is located on the substrate SUB. The substrate SUB and/or the pixel circuit layer PCL may include insulating layers and conductive patterns located between the insulating layers. The conductive patterns of the pixel circuit layer PCL may function as at least a portion of circuit elements, lines, and the like. The conductive patterns may include copper, but embodiments according to the present disclosure are not limited thereto.

The circuit elements may include the sub-pixel circuit SPC (refer to FIG. 2) for each of the first to third sub-pixels SP1, SP2, and SP3. The sub-pixel circuit SPC may include transistors and one or more capacitors. Each transistor may include a semiconductor portion including a source area, a drain area, and a channel area, and a gate electrode overlapping the semiconductor portion. According to some embodiments, when the substrate SUB is provided as a silicon substrate, the semiconductor portion may be included in the substrate SUB, and the gate electrode may be included in the pixel circuit layer PCL as a conductive pattern of the pixel circuit layer PCL. According to some embodiments, when the substrate SUB is provided as a glass substrate or a PI substrate, the semiconductor portion and the gate electrode may be included in the pixel circuit layer PCL. Each capacitor may include electrodes spaced apart from each other. For example, each capacitor may include electrodes spaced apart from each other on a plane defined by the first and second directions DR1 and DR2. For example, each capacitor may include electrodes spaced apart from each other in the third direction DR3 (e.g., in a plan view) with an insulating layer interposed therebetween.

The lines of the pixel circuit layer PCL may include signal lines connected to each of the first to third sub-pixels SP1, SP2, and SP3, for example, a gate line, an emission control line, a data line, and the like. The lines may further include a line connected to the first power voltage node VDDN of FIG. 2. In addition, the lines may further include a line connected to the second power voltage node VSSN of FIG. 2.

The light emitting element layer LDL may include the anode electrodes AE, a pixel defining layer PDL, a light emitting structure EMS, and the cathode electrode CE.

The anode electrodes AE may be located on the pixel circuit layer PCL. The anode electrodes AE may contact the circuit elements of the pixel circuit layer PCL. The anode electrodes AE may include an opaque conductive material capable of reflecting light, but embodiments according to the present disclosure are not limited thereto.

The pixel defining layer PDL is located on the anode electrodes AE. The pixel defining layer PDL may include an opening OP exposing a portion of each of the anode electrodes AE. The opening OP of the pixel defining layer PDL may be understood as emission areas corresponding to the first to third sub-pixels SP1 to SP3, respectively.

According to some embodiments, the pixel defining layer PDL may include an inorganic material. In this case, the pixel defining layer PDL may include a plurality of stacked inorganic layers. For example, the pixel defining layer PDL may include silicon oxide (SiOₓ) and silicon nitride (SiNₓ). According to some embodiments, the pixel defining layer PDL may include an organic material. However, a material of the pixel defining layer PDL is not limited thereto.

The light emitting structure EMS may be located on the anode electrodes AE exposed by the opening OP of the pixel defining layer PDL. The light emitting structure EMS may include a light emitting layer configured to generate light, an electron transport layer configured to transport an electron, a hole transport layer configured to transport a hole, and the like.

According to some embodiments, the light emitting structure EMS may fill the opening OP of the pixel defining layer PDL, and may be entirely located on the pixel defining layer PDL. In other words, the light emitting structure EMS may extend across the first to third sub-pixels SP1 to SP3. In this case, at least a portion of layers in the light emitting structure EMS may be disconnected or bent at boundaries between the first to third sub-pixels SP1 to SP3. However, embodiments according to the present disclosure are not limited thereto. For example, portions of the light emitting structure EMS corresponding to the first to third sub-pixels SP1 to SP3 may be separated from each other, and each of the portions may be located in the opening OP of the pixel defining layer PDL.

The cathode electrode CE may be located on the light emitting structure EMS. The cathode electrode CE may extend across the first to third sub-pixels SP1 to SP3. As described above, the cathode electrode CE may be provided as a common electrode for the first to third sub-pixels SP1 to SP3.

The cathode electrode CE may be a thin metal layer having a thickness sufficient to transmit light emitted from the light emitting structure EMS. The cathode electrode CE may be formed of a metal material or a transparent conductive material to have a relatively thin thickness. According to some embodiments, the cathode electrode CE may include at least one of various transparent conductive materials including indium tin oxide, indium zinc oxide, indium tin zinc oxide, aluminum zinc oxide, gallium zinc oxide, zinc tin oxide, or gallium tin oxide. According to some embodiments, the cathode electrode CE may include at least one of silver (Ag), magnesium (Mg), or a mixture thereof. However, a material of the cathode electrode CE is not limited thereto.

It may be understood that any one of the anode electrodes AE, a portion of the light emitting structure EMS overlapping it, and a portion of the cathode electrode CE overlapping it configure one light emitting element LD (refer to FIG. 2). In other words, each of the light emitting elements of the first to third sub-pixels SP1 to SP3 may include one anode electrode AE, a portion of the light emitting structure EMS overlapping it, and a portion of the cathode electrode CE overlapping it. In each of the first to third sub-pixels SP1 to SP3, holes injected from the anode electrode AE and electrons injected from the cathode electrode CE may be transported into the light emitting layer of the light emitting structure EMS to form excitons, and when the excitons transits from an excited state to a ground state, light may be generated. A luminance of light may be determined according to an amount of a current flowing through the light emitting layer. According to a configuration of the light emitting layer, a wavelength range of the generated light may be determined.

The encapsulation layer TFE is located on the cathode electrode CE. The encapsulation layer TFE may cover the light emitting element layer LDL and/or the pixel circuit layer PCL. The encapsulation layer TFE may be configured to prevent oxygen, moisture, and/or the like from permeating to the light emitting element layer LDL. According to some embodiments, the encapsulation layer TFE may include a structure in which one or more inorganic layers and one or more organic layers are alternately stacked. For example, the inorganic layer may include silicon nitride, silicon oxide, silicon oxynitride (SiOxNy), or the like. For example, the organic layer may include an organic insulating material such as acrylic resin, epoxy resin, phenol resin, polyamide resin, polyimide resin, unsaturated polyester resin, polyphenylenether resin, polyphenylenesulfide resin, or benzocyclobutene (BCB). However, materials of the organic layer and the inorganic layer of the encapsulation layer TFE are not limited thereto.

In order to relatively improve an encapsulation efficiency of the encapsulation layer TFE, the encapsulation layer TFE may further include a thin film including aluminum oxide (AIOx). The thin film including the aluminum oxide may be positioned on an upper surface of the encapsulation layer TFE facing the optical functional layer OFL and/or a lower surface of the encapsulating layer TFE facing the light emitting element layer LDL.

The thin film including the aluminum oxide may be formed through atomic layer deposition (ALD) method. However, embodiments according to the present disclosure are not limited thereto. The encapsulation layer TFE may further include a thin film formed of at least one of various materials suitable for improving the encapsulation efficiency.

The optical functional layer OFL is located on the encapsulation layer TFE. The optical functional layer OFL may include a color filter layer CFL and a lens array LA.

The color filter layer CFL is located between the encapsulation layer TFE and the lens array LA. The color filter layer CFL is configured to filter the light emitted from the light emitting structure EMS and selectively output light of a wavelength range or a color corresponding to each sub-pixel. The color filter layer CFL may include color filters CF respectively corresponding to the first to third sub-pixels SP1 to SP3, and each of the color filters CF may pass light of a wavelength range corresponding to the corresponding sub-pixel. For example, the color filter CF corresponding to the first sub-pixel SP1 may pass red color light, the color filter CF corresponding to the second sub-pixel SP2 may pass green color light, and the color filter CF corresponding to the third sub-pixel SP3 may pass blue color light. According to the light emitted from the light emitting structure EMS of each sub-pixel, at least a portion of the color filters CF may be omitted.

The lens array LA is located on the color filter layer CFL. The lens array LA may include lenses LS respectively corresponding to the first to third sub-pixels SP1 to SP3. Each of the lenses LS may improve light output efficiency by outputting the light emitted from the light emitting structure EMS to an intended path. The lens array LA may have a relatively high refractive index. For example, the lens array LA may have a refractive index higher than that of the overcoat layer OC. According to some embodiments, the lenses LS may include an organic material. According to some embodiments, the lenses LS may include an acrylic material. However, a material of the lenses LS is not limited thereto.

According to some embodiments, compared to the opening OP of the pixel defining layer PDL, at least a portion of the color filters CF of the color filter layer CFL and at least a portion of the lenses LS of the lens array LA may be shifted in a direction parallel to the plane defined by the first and second directions DR1 and DR2. Specifically, in a central area of the display area DA, a center of the color filter CF and a center of the lens LS may be aligned with or overlap with a center of the opening OP of the corresponding pixel definition layer PDL when viewed in the third direction DR3 (e.g., in a plan view). For example, in the central area of the display area DA, the opening OP of the pixel defining layer PDL may completely overlap the corresponding color filter CF of the color filter layer CFL and the corresponding lens LS of the lens array LA. In an area adjacent to the non-display area NDA in the display area DA, the center of the color filter CF and the center of the lens LS may be shifted in a plane direction from the center of the opening OP of the corresponding pixel defining layer PDL when viewed in the third direction DR3 (e.g., in a plan view). For example, in the area adjacent to the non-display area NDA in the display area DA, the opening OP of the pixel defining layer PDL may be partially overlap of the corresponding color filter CF of the color filter layer CFL and the corresponding lens LS of the lens array LA. Accordingly, at a center of the display area DA, the light emitted from the light emitting structure EMS may be efficiently output in a normal direction of a display surface. At an outskirt of the display area DA, the light emitted from the light emitting structure EMS may be efficiently output in a direction inclined by an angle (e.g., a set or predetermined angle) with respect to the normal direction of the display surface.

The overcoat layer OC may be located on the lens array LA. The overcoat layer OC may cover the optical functional layer OFL, the encapsulation layer TFE, the light emitting structure EMS, and/or the pixel circuit layer PCL. The overcoat layer OC may include various materials suitable for protecting layers thereunder from a foreign substance such as dust or moisture. For example, the overcoat layer OC may include at least one of an inorganic insulating layer or an organic insulating layer. For example, the overcoat layer OC may include epoxy, but embodiments according to the present disclosure are not limited thereto. The overcoat layer OC may have a refractive index lower than that of the lens array LA.

The cover window CW may be located on the overcoat layer OC. The cover window CW is configured to protect layers thereunder. The cover window CW may have a refractive index higher than that of the overcoat layer OC. The cover window CW may include glass, but embodiments according to the present disclosure are not limited thereto. For example, the cover window CW may be an encapsulation glass configured to protect components located thereunder. According to some embodiments, the cover window CW may be omitted.

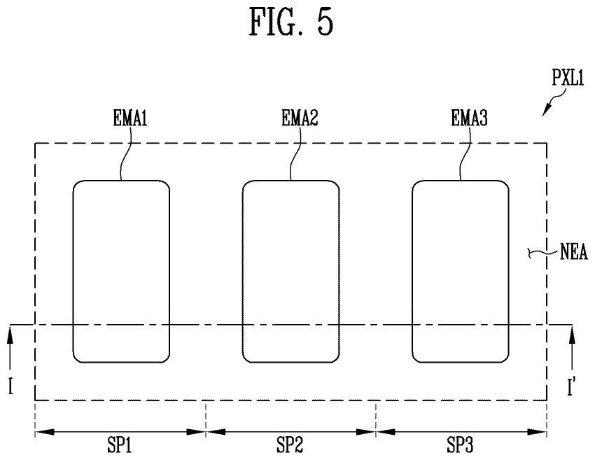

FIG. 5 is a plan view illustrating aspects of a pixel of FIG. 4 according to some embodiments. In FIG. 5, the first pixel PXL1 among the first and second pixels PXL1 and PXL2 of FIG. 4 is schematically shown for clear and concise description. The remaining pixels may be configured similarly to the first pixel PXL1.

Referring to FIGS. 4 and 5, the first pixel PXL1 may include the first to third sub-pixels SP1 to SP3 arranged in the first direction DR1.

The first sub-pixel SP1 may include a first emission area EMA1 and a non-emission area NEA around the first emission area EMA1. The second sub-pixel SP2 may include a second emission area EMA2 and a non-emission area NEA around the second emission area EMA2. The third sub-pixel SP3 may include a third emission area EMA3 and a non-emission area NEA around (e.g., in a periphery or outside a footprint of) the third emission area EMA3.

The first emission area EMA1 may be an area where light is emitted from a portion of the light emitting structure EMS (refer to FIG. 4) corresponding to the first sub-pixel SP1. The second emission area EMA2 may be an area where light is emitted from a portion of the light emitting structure EMS corresponding to the second sub-pixel SP2. The third emission area EMA3 may be an area where light is emitted from a portion of the light emitting structure EMS corresponding to the third sub-pixel SP3. As described with reference to FIG. 5, each emission area may be understood as the opening OP of the pixel defining layer PDL corresponding to each of the first to third sub-pixels SP1 to SP3.

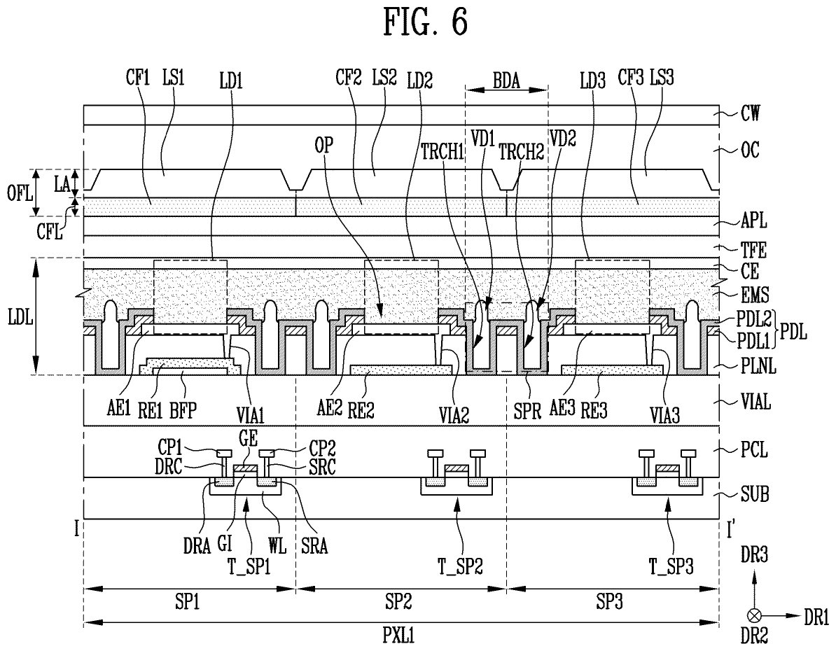

FIG. 6 is a cross-sectional view taken along a line I-I′ of FIG. 5.

Referring to FIG. 6, the substrate SUB and the pixel circuit layer PCL located on the substrate SUB are provided.

The substrate SUB may include a silicon wafer substrate formed using a semiconductor process. For example, the substrate SUB may include silicon, germanium, and/or silicon-germanium.

The pixel circuit layer PCL is located on the substrate SUB. The substrate SUB and the pixel circuit layer PCL may include circuit elements of each of the first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be any one of the transistors included in the sub-pixel circuit SPC (refer to FIG. 2) of the first sub-pixel SP1, the transistor T_SP2 of the second sub-pixel SP2 may be any one of the transistors included in the sub-pixel circuit SPC of the second sub-pixel SP2, and the transistor T_SP3 of the third sub-pixel SP3 may be any one of the transistors included in the sub-pixel circuit SPC of the third sub-pixel SP3. In FIG. 6, for clear and concise description, one of the transistors of each sub-pixel is shown, and the remaining circuit elements are omitted.

The transistor T_SP1 of the first sub-pixel SP1 may include a source area SRA, a drain area DRA, and a gate electrode GE.

The source area SRA and drain area DRA may be located in the substrate SUB. A well WL formed through an ion injection process may be located in the substrate SUB, and the source area SRA and the drain area DRA may be spaced apart from each other in the well WL. An area between the source area SRA and the drain area DRA in the well WL may be defined as a channel area.

The gate electrode GE may overlap the channel area between the source area SRA and the drain area DRA and may be located in the pixel circuit layer PCL. The gate electrode GE may be spaced apart from the well WL or the channel area by an insulating material such as a gate insulating layer GI. The gate electrode GE may include a conductive material.

A plurality of layers included in the pixel circuit layer PCL may include insulating layers and conductive patterns located between the insulating layers, and such conductive patterns may include first and second conductive patterns CP1 and CP2. The first conductive pattern CP1 may be electrically connected to the drain area DRA through a drain connection portion DRC passing through one or more insulating layers. The second conductive pattern CP2 may be electrically connected to the source area SRA through a source connection portion SRC passing through one or more insulating layers.

As the gate electrode GE and the first and second conductive patterns CP1 and CP2 are connected to different circuit elements and/or lines, the transistor T_SP1 of the first sub-pixel SP1 may be provided as any one of the transistors of the first sub-pixel SP1.

Each of the transistor T_SP2 of the second sub-pixel SP2 and the transistor T_SP3 of the third sub-pixel SP3 may be configured similarly to the transistor T_SP1 of the first sub-pixel SP1.

As described above, the substrate SUB and the pixel circuit layer PCL may include the circuit elements of each of the first to third sub-pixels SP1 to SP3.

A via layer VIAL is located on the pixel circuit layer PCL. The via layer VIAL may cover the pixel circuit layer PCL and may have an overall flat or planar surface. The via layer VIAL is configured to planarize operations on the pixel circuit layer PCL. The via layer VIAL may include at least one of silicon oxide (SiOₓ), silicon nitride (SiNₓ), or silicon carbon nitride (SiCN), but embodiments according to the present disclosure are not limited thereto.

The light emitting element layer LDL is located on the via layer VIAL. The light emitting element layer LDL may include first to third reflective electrodes RE1 to RE3, a planarization layer PLNL, first to third anode electrodes AE1 to AE3, the pixel defining layer PDL, the light emitting structure EMS, and the cathode electrode CE.

On the via layer VIAL, the first to third reflective electrodes RE1 to RE3 are located in the first to third sub-pixels SP1 to SP3, respectively. Each of the first to third reflective electrodes RE1 to RE3 may contact the circuit element located in the pixel circuit layer PCL through a via passing through the via layer VIAL.

The first to third reflective electrodes RE1 to RE3 may function as a full mirror reflecting the light emitted from the light emitting structure EMS toward the display surface (or the cover window CW). The first to third reflective electrodes RE1 to RE3 may include metal materials suitable for reflecting light. The first to third reflective electrodes RE1 to RE3 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), or an alloy of two or more materials selected from them, but embodiments according to the present disclosure are not limited thereto.

According to some embodiments, a connection electrode may be located under each of the first to third reflective electrodes RE1 to RE3. The connection electrode may improve an electrical connection characteristic between a corresponding reflective electrode and the circuit element of the pixel circuit layer PCL. The connection electrode may have a multilayer structure. The multilayer structure may include titanium (Ti), titanium nitride (TiN), tantalum nitride (TaN), or the like, but embodiments according to the present disclosure are not limited thereto. According to some embodiments, a corresponding reflective electrode may be positioned between multiple layers of the connection electrode.

A buffer pattern BFP may be located under at least one of the first to third reflective electrodes RE1 to RE3. The buffer pattern BFP may include an inorganic material such as silicon carbon nitride, but embodiments according to the present disclosure are not limited thereto. By forming the buffer pattern BFP, a height in the third direction DR3 of a corresponding reflective electrode may be adjusted. For example, the buffer pattern BFP may be located between the first reflective electrode RE1 and the via layer VIAL to adjust a height of the first reflective electrode RE1.

The first to third reflective electrodes RE1 to RE3 may function as full mirrors, and the cathode electrode CE may function as a half mirror. The light emitted from the light emitting layer of the light emitting structure EMS may be amplified by at least partially reciprocating between a corresponding reflective electrode and the cathode electrode CE, and the amplified light may be output through the cathode electrode CE. As described above, a distance between each reflective electrode and the cathode electrode CE may be understood as a resonance distance for the light emitted from the light emitting layer of the corresponding light emitting structure EMS.

The first sub-pixel SP1 may have a resonance distance shorter than that of another sub-pixel by the buffer pattern BFP. The resonance distance adjusted as described above may allow light of a specific wavelength range (for example, red color) to be effectively and efficiently amplified. Accordingly, the first sub-pixel SP1 may effectively and efficiently output light of a corresponding wavelength range.

In FIG. 6, the buffer pattern BFP is provided to the first sub-pixel SP1 and is not provided to the second and third sub-pixels SP2 and SP3, but embodiments according to the present disclosure are not limited thereto. The buffer pattern may also be provided to at least one of the second or third sub-pixels SP2 or SP3 to adjust the resonance distance of at least one of the second or third sub-pixels SP2 or SP3. For example, the buffer pattern BFP may also be provided to the second sub-pixel SP2, and the resonance distance of the second sub-pixel SP2 may be adjusted. For example, the first to third sub-pixels SP1 to SP3 may correspond to red, green, and blue, respectively, a distance between the first reflective electrode RE1 and the cathode electrode CE may be shorter than a distance between the second reflective electrode RE2 and the cathode electrode CE, and the distance between the second reflective electrode RE2 and the cathode electrode CE may be shorter than a distance between the third reflective electrode RE3 and the cathode electrode CE.

In order to planarize operations between the first to third reflective electrodes RE1 to RE3, a planarization layer PLNL may be located on the via layer VIAL and the first to third reflective electrodes RE1 to RE3. The planarization layer PLNL may generally cover the first to third reflective electrodes RE1 to RE3 and the via layer VIAL, and may have a flat surface. According to some embodiments, the planarization layer PLNL may be omitted

On the planarization layer PLNL, the first to third anode electrodes AE1 to AE3 respectively overlapping the first to third reflective electrodes RE1 to RE3 are located. The first to third anode electrodes AE1 to AE3 may have shapes similar to those of the first to third emission areas EMA1 to EMA3 of FIG. 5 when viewed in the third direction DR3 (e.g., in a plan view). The first to third anode electrodes AE1 to AE3 are respectively connected to the first to third reflective electrodes RE1 to RE3. The first anode electrode AE1 may be connected to the first reflective electrode RE1 through a first via VIA1 passing through the planarization layer PLNL. The second anode electrode AE2 may be connected to the second reflective electrode RE2 through a second via VIA2 passing through the planarization layer PLNL. The third anode electrode AE3 may be connected to the third reflective electrode RE3 through a third via VIA3 passing through the planarization layer PLNL.

According to some embodiments, the first to third anode electrodes AE1 to AE3 may include at least one of transparent conductive materials such as indium tin oxide (ITO), indium zinc oxide (IZO), zinc oxide (ZnOₓ), indium gallium zinc oxide (IGZO), or indium tin zinc oxide (ITZO). However, a material of the first to third anode electrodes AE1 to AE3 is not limited thereto. For example, the first to third anode electrodes AE1 to AE3 may include titanium nitride.

According to some embodiments, insulating layers for adjusting a height of one or more of the first to third anode electrodes AE1 to AE3 may be further provided. The insulating layers may be located between one or more of the first to third anode electrodes AE1 to AE3 and corresponding reflective electrodes. In this case, the planarization layer PLNL and/or the buffer pattern BFP may be omitted. For example, the first to third sub-pixels SP1 to SP3 may correspond to red, green, and blue, respectively, a distance between the first anode electrode AE1 and the cathode electrode CE may be shorter than a distance between the second anode electrode AE2 and the cathode electrode CE, and the distance between the second anode electrode AE2 and the cathode electrode CE may be shorter than a distance between the third anode electrode AE3 and the cathode electrode CE. The pixel defining layer PDL is located on portions of the first to third anode electrodes AE1 to AE3 and the planarization layer PLNL. The pixel defining layer PDL may include an opening OP exposing a portion of each of the first to third anode electrodes AE1 to AE3. The opening OP of the pixel defining layer PDL may define the emission area of each of the first to third sub-pixels SP1 to SP3. As described above, the pixel defining layer PDL may be located in the non-emission area NEA of FIG. 5 and may define the first to third emission areas EMA1 to EMA3 of FIG. 5.

According to some embodiments, the pixel defining layer PDL may include a plurality of inorganic insulating layers. Each of the plurality of inorganic insulating layers may include at least one of silicon oxide (SiOₓ) or silicon nitride (SiNₓ). For example, the pixel defining layer PDL may include sequentially stacked first and second inorganic insulating layers (that is, a first pixel defining layer PDL1 and a second pixel defining layer PDL2), and each of the first and second inorganic insulating layers may include silicon nitride, silicon oxide, and silicon oxynitride. However, embodiments according to the present disclosure are not limited thereto.

For convenience of description, in FIG. 6, a thickness of the first pixel defining layer PDL1 and a thickness the second pixel defining layer PDL2 are the same, and the thickness of the second pixel defining layer PDL2 is constant in all areas, but the disclosure is not limited thereto. A description of a specific shape of the first pixel defining layer PDL1 and the second pixel defining layer PDL2 is described later.

A separator SPR may be provided in a boundary area BDA between sub-pixels neighboring each other. In other words, the separator SPR may be provided in each of the boundary areas between the sub-pixels SP of FIG. 4.

The separator SPR may cause formation of a discontinuity in the light emitting structure EMS in the boundary area BDA. For example, the light emitting structure EMS may be disconnected or bent in the boundary area BDA due to the separator SPR.

The separator SPR may be provided in or on the pixel defining layer PDL. The pixel defining layer PDL may include one or more trenches TRCH1 and TRCH2 as the separator SPR in the boundary area BDA. According to some embodiments, as shown in FIG. 6, one or more trenches TRCH1 and TRCH2 may pass through the pixel defining layer PDL and partially pass through the planarization layer PLNL. According to some embodiments, one or more trenches TRCH1 and TRCH2 may pass through the pixel defining layer PDL and the planarization layer PLNL, and may partially pass through the via layer VIAL. According to some embodiments, one or more trenches TRCH1 and TRCH2 at least partially pass through the planarization layer PLNL and/or the via layer VIAL, and a portion of the pixel defining layer PDL may be located in one or more trenches TRCH1 and TRCH2.

In FIG. 6, the two trenches TRCH1 and TRCH2 are provided in the boundary area BDA. However, embodiments according to the present disclosure are not limited thereto. For example, the pixel defining layer PDL may include one trench in the boundary area BDA. Alternatively, the pixel defining layer PDL may include three or more trenches in the boundary area BDA.

Due to the first and second trenches TRCH1 and TRCH2, in the boundary area BDA, discontinuous portions such as a first void VD1 and a second void VD2 may be formed in the light emitting structure EMS. A portion of a plurality of layers stacked in the light emitting structure EMS may be disconnected or bent by the first and second voids VD1 and VD2. For example, at least one charge generation layer included in the light emitting structure EMS may be disconnected in the first and second voids VD1 and VD2. As described above, portions of the light emitting structure EMS included in the first to third sub-pixels SP1 to SP3 may be at least partially separated due to the first and second trenches TRCH1 and TRCH2.

In FIG. 6, in the boundary area BDA, the first and second voids VD1 and VD2 are formed in the light emitting structure EMS, but this is merely illustrative, and embodiments according to the present disclosure are not limited thereto. For example, in the boundary area BDA, a valley of a concave shape may be formed in the light emitting structure EMS. According to shapes of the first and second trenches TRCH1 and TRCH2, discontinuous portions formed in the light emitting structure EMS may be variously changed.

According to some embodiments, the light emitting structure EMS may be formed through a process of vacuum deposition, inkjet printing, and the like. In this case, the same materials as the light emitting structure EMS may be positioned on bottom surfaces of the first and second trenches TRCH1 and TRCH2 adjacent to the via layer VIAL.

The separator SPR may be variously modified and provided so that the light emitting structure EMS may have a discontinuous portion in the boundary area BDA.

The light emitting structure EMS may be located on the anode electrodes AE exposed by the opening OP of the pixel defining layer PDL. The light emitting structure EMS may fill the opening OP of the pixel defining layer PDL and may be located entirely across the first to third sub-pixels SP1 to SP3. As described above, the light emitting structure EMS may be at least partially disconnected or bent in the boundary area BDA by the separator SPR. Accordingly, when the display panel DP is operated, a current flowing out from each of the first to third sub-pixels SP1 to SP3 to a sub-pixel adjacent thereto through layers included in the light emitting structure EMS may decrease. Therefore, the first to third light emitting elements LD1 to LD3 may operate with relatively high reliability.

The cathode electrode CE may be located on the light emitting structure EMS. The cathode electrode CE may be commonly provided to the first to third sub-pixels SP1 to SP3. The cathode electrode CE may function as a half mirror that partially transmits and partially reflects the light emitted from the light emitting structure EMS.

The first anode electrode AE1, a portion of the light emitting structure EMS overlapping the first anode electrode AE1, and a portion of the cathode electrode CE overlapping the first anode electrode AE1 may configure the first light emitting element LD1. The second anode electrode AE2, a portion of the light emitting structure EMS overlapping the second anode electrode AE2, and a portion of the cathode electrode CE overlapping the second anode electrode AE2 may configure the second light emitting element LD2. The third anode electrode AE3, a portion of the light emitting structure EMS overlapping the third anode electrode AE3, and a portion of the cathode electrode CE overlapping the third anode electrode AE3 may configure the third light emitting element LD3.

The encapsulation layer TFE is located on the cathode electrode CE. The encapsulation layer TFE may prevent oxygen, moisture, and/or the like from permeating to the light emitting element layer LDL.

The optical functional layer OFL is located on the encapsulation layer TFE. According to some embodiments, the optical functional layer OFL may be attached to the encapsulation layer TFE through an adhesive layer APL. For example, the optical functional layer OFL may be separately manufactured and attached to the encapsulation layer TFE through the adhesive layer APL. The adhesive layer APL may further perform a function of protecting lower layers including the encapsulation layer TFE.

The optical functional layer OFL may include the color filter layer CFL and the lens array LA. The color filter layer CFL may include first to third color filters CF1 to CF3 respectively corresponding to the first to third sub-pixels SP1 to SP3. The first to third color filters CF1 to CF3 may pass light of different wavelength ranges. For example, the first to third color filters CF1 to CF3 may pass light of red, green, and blue colors, respectively.

According to some embodiments, the first to third color filters CF1 to CF3 may partially overlap in the boundary area BDA. According to some embodiments, the first to third color filters CF1 to CF3 may be spaced apart from each other, and a black matrix may be provided between the first to third color filters CF1 to CF3.

The lens array LA is located on the color filter layer CFL. The lens array LA may include first to third lenses LS1 to LS3 respectively corresponding to the first to third sub-pixels SP1 to SP3. Each of the first to third lenses LS1 to LS3 may improve light output efficiency by outputting light emitted from the first to third light emitting elements LD1 to LD3 to an intended path.

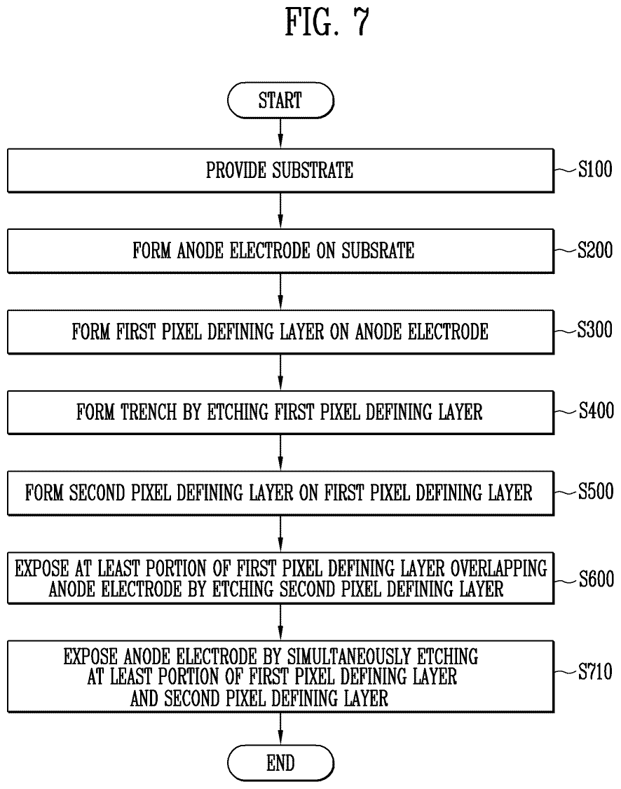

FIG. 7 is a flowchart illustrating aspects of a method of manufacturing a display device according to some embodiments of the disclosure. Although various operations are illustrated in FIG. 7, embodiments according to the present disclosure are not limited thereto. For example, according to some embodiments, there may be additional operations or fewer operations, or the order of operations may vary, unless otherwise explicitly stated or implied, without departing from the spirit and scope of embodiments according to the present disclosure.

Referring to FIG. 7, the method of manufacturing the display device may provide a substrate (S100), form an anode electrode on the substrate (S200), form a first pixel defining layer on the anode electrode (S300), form a trench by etching the first pixel defining layer (S400), form a second pixel defining layer on the first pixel defining layer (S500), expose at least a portion of the first pixel defining layer overlapping the anode electrode by etching the second pixel defining layer (S600), and expose the anode electrode by simultaneously etching the at least the portion of the first pixel defining layer and the second pixel defining layer (S710).

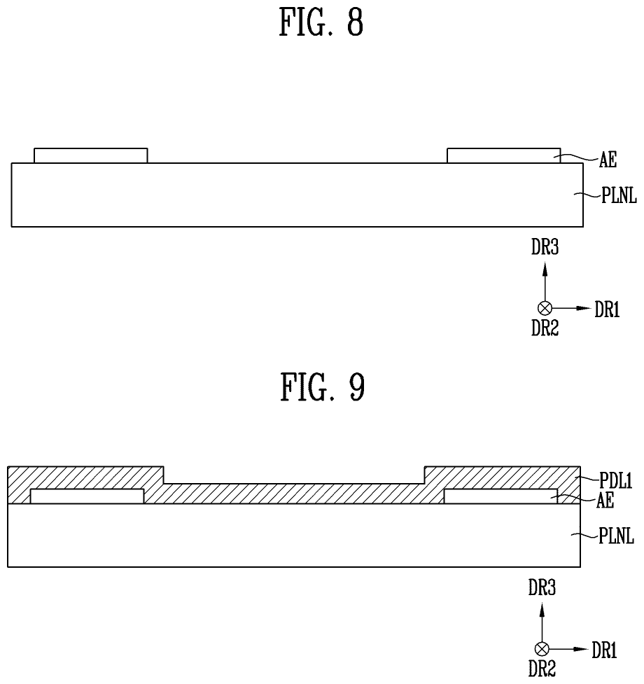

Hereinafter, the disclosure is specifically described with reference to FIGS. 8 to 13.

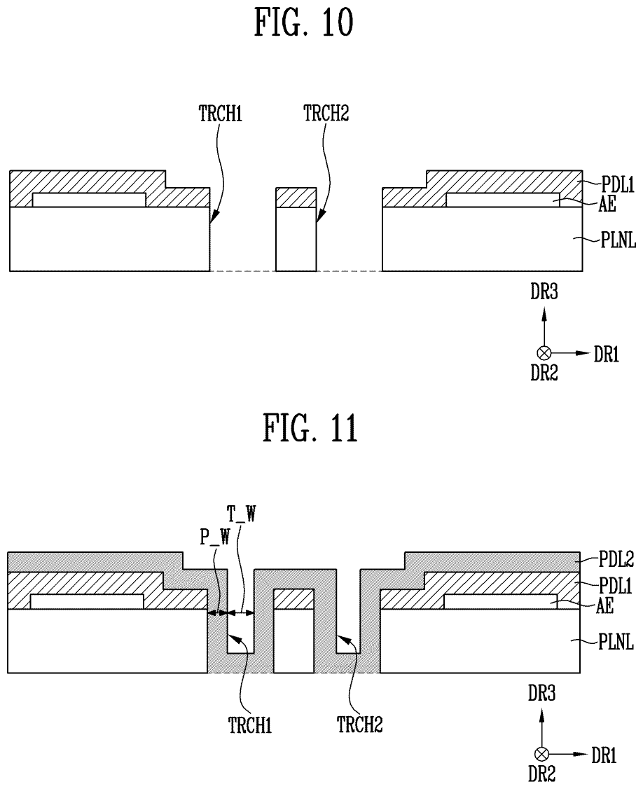

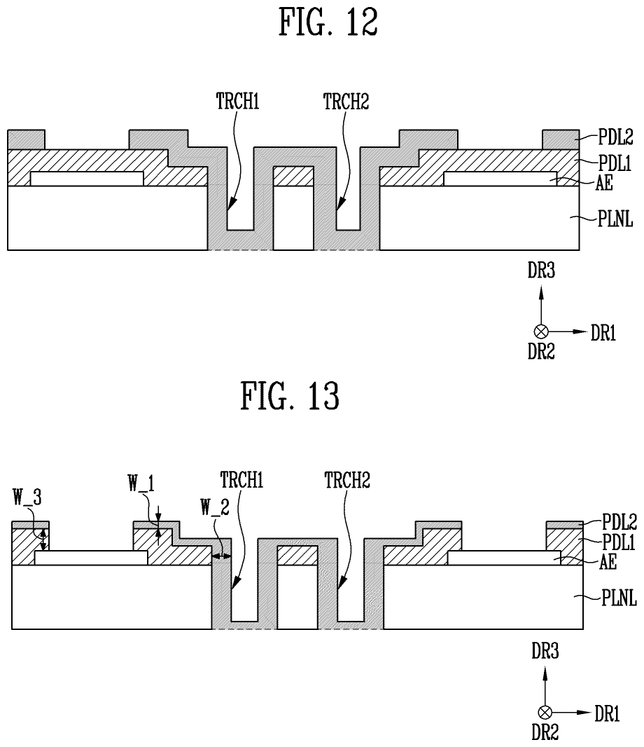

FIG. 8 is a diagram illustrating an example of operation S200 of FIG. 7, FIG. 9 is a diagram illustrating an example of operation S300 of FIG. 7, FIG. 10 is a diagram illustrating an example of operation S400 of FIG. 7, FIG. 11 is a diagram illustrating an example of operation S500 of FIG. 7, FIG. 12 is a diagram illustrating an example of operation S600 of FIG. 7, and FIG. 13 is a diagram illustrating an example of operation S710 of FIG. 7.

In FIGS. 8 to 13, for convenience of description, configurations except for the planarization layer PLNL, the anode electrode AE, and the pixel defining layers PDL1 and PDL2 are omitted. In addition, for convenience of description, in FIGS. 8 to 13, the trenches TRCH1 and TRCH2 pass through the planarization layer PLNL, but the disclosure is not limited thereto. For example, the trenches TRCH1 and TRCH2 may partially pass through the planarization layer PLNL. For example, the trenches TRCH1 and TRCH2 may at least partially pass through the via layer VIAL.

Referring to FIG. 8, the anode electrode AE may be formed on the planarization layer PLNL. Because the planarization layer PLNL and the anode electrode AE are described with reference to FIG. 6, a description of the planarization layer PLNL and the anode electrode AE is omitted.

Referring to FIGS. 9 and 10, the first pixel defining layer PDL1 may be formed on the anode electrode AE and the planarization layer PLNL. The first pixel defining layer PDL1 and the planarization layer PLNL may be etched to form the trenches TRCH1 and TRCH2. For example, the trenches TRCH1 and TRCH2 may be formed by etching the first pixel defining layer PDL1 and the planarization layer PLNL through photolithography. According to some embodiments, the trenches TRCH1 and TRCH2 may at least partially pass through the via layer VIAL. In this case, the via layer VIAL may be etched to form the trenches TRCH1 and TRCH2.

Referring to FIGS. 6 and 11, the second pixel defining layer PDL2 may be formed on the first pixel defining layer PDL1. A thickness P_W at which the second pixel defining layer PDL2 is formed may be determined according to a width T_W of the trenches TRCH1 and TRCH2. By adjusting the thickness P_W at which the second pixel defining layer PDL2 is formed, the width T_W of the trenches TRCH1 and TRCH2 may be adjusted.

When the width T_W of the trenches TRCH1, TRCH2 is excessively wide, disconnection may occur in forming the cathode electrode CE. However, as the second pixel defining layer PDL2 is formed on an upper surface of the first pixel defining layer PDL1 and on a side surface of the first pixel defining layer PDL1, the width T_W of the trenches TRCH1 and TRCH2 may be narrowed.

Referring to FIG. 12, at least a portion of the first pixel defining layer PDL1 overlapping the anode electrode AE may be exposed by etching the second pixel defining layer PDL2.

Referring to FIG. 13, the anode electrode AE may be exposed by simultaneously etching the at least the portion of the first pixel defining layer PDL1 and the second pixel defining layer PDL2. For example, the at least the portion of the first pixel defining layer PDL1 and the second pixel defining layer PDL2 may be etched through an etch back process. Accordingly, the thickness W_1 of the second pixel defining layer PDL2 formed on the upper surface of the first pixel defining layer PDL1 may be thinner than a thickness W_2 of the second pixel defining layer PDL2 formed on the side surface of the first pixel defining layer PDL1. Here, the etch back process is a process of entirely etching without patterning before etching.

An etch speed of the second pixel defining layer PDL2 may be slower than an etch speed of the at least the portion of the first pixel defining layer PDL1. Accordingly, even though the at least the portion of the first pixel defining layer PDL1 is etched and the anode electrode AE is exposed, a portion of the second pixel defining layer PDL2 may remain. That is, the second pixel defining layer PDL2 may serve as a mask of the first pixel defining layer PDL1. Therefore, the method of manufacturing the display device according to the disclosure may expose the anode electrode AE by etching the first pixel defining layer PDL1 without separate patterning. That is, the method of manufacturing the display device according to the disclosure may simplify the manufacturing process.

Because the etch speed of the second pixel defining layer PDL2 is slower than the etch speed of the at least the portion of the first pixel defining layer PDL1, an extent to which the second pixel defining layer PDL2 is etched may be less than an extent to which the at least the portion of the first pixel defining layer PDL1 is etched. In addition, the at least the portion of the first pixel defining layer PDL1 may be etched until the anode electrode AE is exposed. Therefore, a thickness W_3 of the first pixel defining layer PDL1 corresponding to the extent to which the first pixel defining layer PDL1 is etched may be greater than a difference between the thickness W_2 of the second pixel defining layer PDL2 formed on the side surface of the first pixel defining layer PDL1 corresponding to the extent to which the second pixel defining layer PDL2 is etched and the thickness W_1 of the second pixel defining layer PDL2 formed on the upper surface of the first pixel defining layer PDL1.

According to some embodiments, the first pixel defining layer PDL1 and the second pixel defining layer PDL2 may be formed through different processes. For example, the first pixel defining layer PDL1 may be formed in a chemical vapor deposition (CVD) method, and the second pixel defining layer PDL2 may be formed in an atomic layer deposition (ALD) method. For example, the first pixel defining layer PDL1 may be formed in a plasma enhanced chemical vapor deposition (PECVD) method. That is, due to a difference of a deposition method, a density difference between the first pixel defining layer PDL1 and the second pixel defining layer PDL2 may occur, and thus a difference of an etch speed may occur between the first pixel defining layer PDL1 and the second pixel defining layer PDL2. In this case, the first pixel defining layer PDL1 and the second pixel defining layer PDL2 may include the same material. For example, the first pixel defining layer PDL1 and the second pixel defining layer PDL2 may include silicon oxide (SiOₓ). However, the disclosure is not limited thereto.

According to some embodiments, the first pixel defining layer PDL1 and the second pixel defining layer PDL2 may include different materials. For example, the first pixel defining layer PDL1 may include silicon oxide (SiOₓ), and the second pixel defining layer PDL2 may include silicon nitride (SiNₓ). That is, due to a difference of included materials, a difference of an etch speed may occur between the first pixel defining layer PDL1 and the second pixel defining layer PDL2.

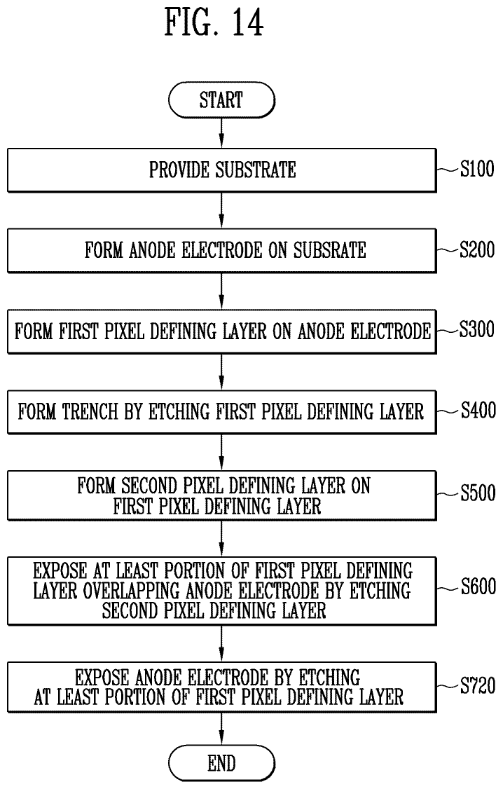

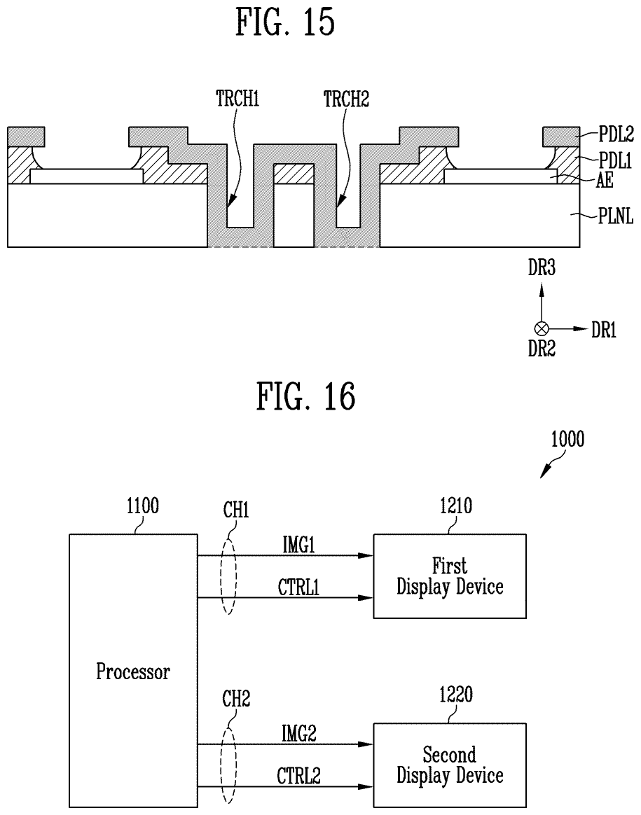

FIG. 14 is a flowchart illustrating a method of manufacturing a display device according to some embodiments of the present disclosure, and FIG. 15 is a diagram illustrating an example of operation S720 of FIG. 14. Although various operations are illustrated in FIG. 14, embodiments according to the present disclosure are not limited thereto. For example, according to some embodiments, there may be additional operations or fewer operations, or the order of operations may vary, unless otherwise explicitly stated or implied, without departing from the spirit and scope of embodiments according to the present disclosure.

Because the method of manufacturing the display device according to the present embodiments is substantially the same as the method of manufacturing the display device as illustrated with respect to FIG. 7 except for operation S720, the same reference numbers and reference symbols are used for the equal or similar components, and some overlapping description may omitted.

Referring to FIG. 14, the method of manufacturing the display device may provide a substrate (S100), form an anode electrode on the substrate (S200), form a first pixel defining layer on the anode electrode (S300), form a trench by etching the first pixel defining layer (S400), form a second pixel defining layer on the first pixel defining layer (S500), expose at least a portion of the first pixel defining layer overlapping the anode electrode by etching the second pixel defining layer (S600), and expose the anode electrode by etching the at least the portion of the first pixel defining layer (S720).

Referring to FIG. 15, at least the portion of the first pixel defining layer PDL1 may be etched through wet etching. An etch speed by an etching solution of the wet etching of the first pixel defining layer PDL1 may be faster than that of the second pixel defining layer PDL2. Accordingly, even though the at least the portion of the first pixel defining layer PDL1 is etched and the anode electrode AE is exposed, a portion of the second pixel defining layer PDL2 may remain. That is, the second pixel defining layer PDL2 may serve as a mask of the first pixel defining layer PDL1. Therefore, the method of manufacturing the display device according to the disclosure may expose the anode electrode AE by etching the first pixel defining layer PDL1 without separate patterning. That is, the method of manufacturing the display device according to the disclosure may simplify the manufacturing process.

According to some embodiments, the first pixel defining layer PDL1 may include silicon oxide (SiOₓ), and the second pixel defining layer PDL2 may include silicon nitride (SiNₓ). In this case, the etching solution of the wet etching may include a buffered oxide etchant (BOE) solution or a tetramethyl ammonium hydroxide (TMAH) solution. That is, a solution for etching oxide may be determined as the etching solution.

According to some embodiments, the first pixel defining layer PDL1 may include silicon nitride (SiNₓ), and the second pixel defining layer PDL2 may include silicon oxide (SiOₓ). In this case, the etching solution for the wet etching may include phosphoric acid. That is, the solution for etching nitride may be determined as the etching solution.

However, the first pixel defining layer PDL1 and the second pixel defining layer PDL2 do not necessarily have to include different materials.

FIG. 16 is a block diagram illustrating aspects of a display system according to some embodiments.

Referring to FIG. 16, the display system 1000 may include a processor 1100 and one or more display devices 1210 and 1220. Similarly, in manufacturing the display devices 1210 and 1220 of the display system 1000, a manufacturing process of the display system 1000 may be simplified using a second pixel defining layer as a mask of a first pixel defining layer.

The processor 1100 may perform various tasks and calculations. According to some embodiments, the processor 1100 may include an application processor, a graphic processor, a microprocessor, a central processing unit (CPU), and the like. The processor 1100 may be connected to other components of the display system 1000 through a bus system and may control the other components.

In FIG. 16, the display system 1000 includes the first and second display devices 1210 and 1220. The processor 1100 may be connected to the first display device 1210 through a first channel CH1 and may be connected to the second display device 1220 through a second channel CH2.

Through the first channel CH1, the processor 1100 may transmit first image data IMG1 and a first control signal CTRL1 to the first display device 1210. The first display device 1210 may display an image based on the first image data IMG1 and the first control signal CTRL1. The first display device 1210 may be configured similarly to the display device 100 described with reference to FIG. 1. In this case, the first image data IMG1 and the first control signal CTRL1 may be provided as the input image data IMG and the control signal CTRL of FIG. 1, respectively.

Through the second channel CH2, the processor 1100 may transmit second image data IMG2 and a second control signal CTRL2 to the second display device 1220. The second display device 1220 may display an image based on the second image data IMG2 and the second control signal CTRL2. The second display device 1220 may be configured similarly to the display device 100 described with reference to FIG. 1. In this case, the second image data IMG2 and the second control signal CTRL2 may be provided as the input image data IMG and the control signal CTRL of FIG. 1, respectively.

The display system 1000 may include a computing system providing an image display function, such as a portable computer, a mobile phone, a smart phone, a tablet personal computer (PC), a smart watch, a watch phone, a portable multimedia player (PMP), a navigation device, and an ultra mobile personal computer (UMPC). In addition, the display system 1000 may include at least one of a head mounted display (HMD) device, a virtual reality (VR) device, a mixed reality (MR) device, or an augmented reality (AR) device.

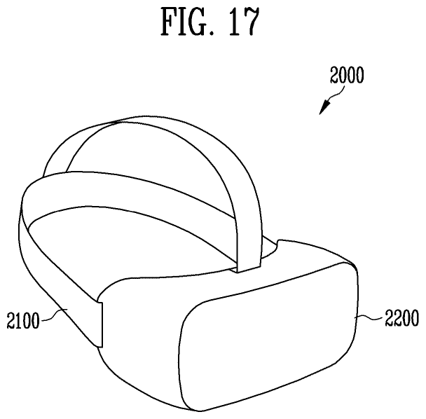

FIG. 17 is a perspective view illustrating an application example of the display system of FIG. 16.

Referring to FIG. 17, the display system 1000 of FIG. 16 may be applied to a head mounted display device 2000. The head mounted display device 2000 may be a wearable electronic device that may be worn on a user's head.

The head mounted display device 2000 may include a head mount band 2100 and a display device accommodation case 2200. The head mount band 2100 may be connected to the display device accommodation case 2200. The head mount band 2100 may include a horizontal band and/or a vertical band for fixing the head mounted display device 2000 to the user's head. The horizontal band may be configured to surround a side portion of the user's head, and the vertical band may be configured to surround an upper portion of the user's head. However, embodiments according to the present disclosure are not limited thereto. For example, the head mount band 2100 may be implemented in a glasses frame form, a helmet form, or the like.

The display device accommodation case 2200 may accommodate the first and second display devices 1210 and 1220 of FIG. 16. The display device accommodation case 2200 may further accommodate the processor 1100 of FIG. 16.

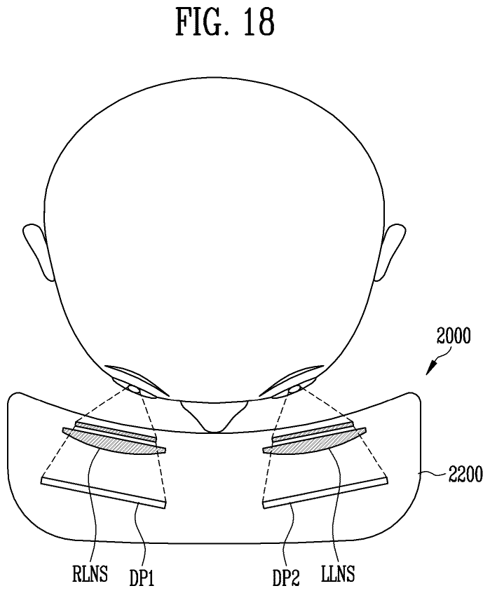

FIG. 18 is a diagram illustrating the head mounted display device worn by a user of FIG. 17.

Referring to FIG. 18, in a head mounted display device 2000, a first display panel DP1 of the first display device 1210 and a second display panel DP2 of the second display device 1220 are located. The head mounted display device 2000 may further include one or more lenses (e.g., a left eye lens LLNS and a right eye lens RLNS).

Within the display device accommodation case 2200, the right eye lens RLNS may be located between the first display panel DP1 and a user's right eye. Within the display device accommodation case 2200, the left eye lens LLNS may be located between the second display panel DP2 and a user's left eye.

An image output from the first display panel DP1 may be displayed to the user's right eye through the right eye lens RLNS. The right eye lens RLNS may refract light from the first display panel DP1 to be directed toward the user's right eye. The right eye lens RLNS may perform an optical function for adjusting a viewing distance between the first display panel DP1 and the user's right eye.

An image output from the second display panel DP2 may be displayed to the user's left eye through the left eye lens LLNS. The left eye lens LLNS may refract light from the second display panel DP2 to be directed toward the user's left eye. The left eye lens LLNS may perform an optical function for adjusting a viewing distance between the second display panel DP2 and the user's left eye.

According to some embodiments, each of the right eye lens RLNS and the left eye lens LLNS may include an optical lens having a pancake-shaped cross-section. According to some embodiments, each of the right eye lens RLNS and the left eye lens LLNS may include a multi-channel lens including sub-areas having different optical characteristics. In this case, each display panel may output images respectively corresponding to the sub-areas of the multi-channel lens, and the output images may pass through the respective corresponding sub-areas and may be viewed to the user.

Although specific embodiments and application examples are described herein, other embodiments and modifications may be derived from the above description. Therefore, the spirit of the disclosure is not limited to such embodiments, and extends to the scope of the claims set forth below, various obvious modifications, and equivalents.

The disclosure may be applied to a display device and an electronic device including the display device. For example, the disclosure may be applied to a digital TV, a 3D TV, a mobile phone, a smart phone, a tablet computer, a VR device, a PC, a home electronic device, a notebook computer, a PDA, a PMP, a digital camera, a music player, a portable game console, a navigation system, and the like.

The electronic or electric devices and/or any other relevant devices or components according to embodiments of the present invention described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the disclosed embodiments of the present invention.

Although described with reference to the above embodiments, it will be understood that those skilled in the art can variously modify and change the disclosure without departing from the spirit and scope of the disclosure described in the claims below, and their equivalents.

What is claimed is:

1. A method of manufacturing a display device, the method comprising:
providing a substrate;
forming an anode electrode on the substrate;
forming a first insulating layer on the anode electrode;
forming a trench by etching the first insulating layer;
forming a second insulating layer on the first insulating layer through a process different from that of the first insulating layer;
exposing at least a portion of the first insulating layer overlapping the anode electrode by etching the second insulating layer; and
exposing the anode electrode by concurrently etching the at least the portion of the first insulating layer and the second insulating layer.

2. The method according to claim 1, wherein in exposing the anode electrode, an etch speed of the second insulating layer is slower than an etch speed of the at least the portion of the first insulating layer.

3. The method according to claim 1, wherein the first insulating layer is formed in a chemical vapor deposition (CVD) deposition operation.

4. The method according to claim 1, wherein the second insulating layer is formed in an atomic layer deposition (ALD) operation.

5. The method according to claim 1, wherein after the anode electrode is exposed, a thickness of the second insulating layer formed on an upper surface of the first insulating layer is thinner than a thickness of the second insulating layer formed on a side surface of the first insulating layer.

6. The method according to claim 1, wherein a thickness at which the second insulating layer is formed is determined according to a width of the trench.

7. The method according to claim 1, wherein in exposing the anode electrode, the at least the portion of the first insulating layer and the second insulating layer are etched through an etch back process.

8. A method of manufacturing a display device, the method comprising:
providing a substrate;
forming an anode electrode on the substrate;
forming a first insulating layer on the anode electrode;
forming a trench by etching the first insulating layer;
forming a second insulating layer including a material different from that of the first insulating layer on the first insulating layer;
exposing at least a portion of the first insulating layer overlapping the anode electrode by etching the second insulating layer; and
exposing the anode electrode by concurrently etching the at least the portion of the first insulating layer and the second insulating layer.

9. The method according to claim 8, wherein in exposing the anode electrode, an etch speed of the second insulating layer is slower than an etch speed of the at least the portion of the first insulating layer.

10. The method according to claim 8, wherein the first insulating layer includes silicon oxide, and
the second insulating layer includes silicon nitride.

11. The method according to claim 8, wherein after the anode electrode is exposed, a thickness of the second insulating layer formed on an upper surface of the first insulating layer is thinner than a thickness of the second insulating layer formed on a side surface of the first insulating layer.

12. The method according to claim 8, wherein a thickness at which the second insulating layer is formed is determined according to a width of the trench.

13. The method according to claim 8, wherein in exposing the anode electrode, the at least the portion of the first insulating layer and the second insulating layer are etched through an etch back process.

14. A method of manufacturing a display device, the method comprising:
providing a substrate;
forming an anode electrode on the substrate;
forming a first insulating layer on the anode electrode;
forming a trench by etching the first insulating layer;
forming a second insulating layer on the first insulating layer;
exposing at least a portion of the first insulating layer overlapping the anode electrode by etching the second insulating layer; and
exposing the anode electrode by etching the at least the portion of the first insulating layer.

15. The method according to claim 14, wherein in exposing the anode electrode, the at least the portion of the first insulating layer is etched through wet etching.

16. The method according to claim 15, wherein an etch speed of the first insulating layer by an etching solution of the wet etching is faster than that of the second insulating layer.

17. The method according to claim 15, wherein the first insulating layer includes silicon oxide,
the second insulating layer includes silicon nitride, and
an etching solution of the wet etching includes a buffered oxide etchant (BOE) solution.

18. The method according to claim 15, wherein the first insulating layer includes silicon oxide,
the second insulating layer includes silicon nitride, and
an etching solution of the wet etching includes a tetramethyl ammonium hydroxide (TMAH) solution.

19. The method according to claim 15, wherein the first insulating layer is silicon nitride,
the second insulating layer is silicon oxide, and
an etching solution of the wet etching includes phosphoric acid.

20. A display device comprising:
a substrate;
an anode electrode on the substrate;
a first insulating layer on the anode electrode;
a second insulating layer on the first insulating layer;
a light emitting structure on the anode electrode and exposed by openings of the first insulating layer and the second insulating layer; and
a cathode electrode on the light emitting structure,
wherein a difference between a thickness of the second insulating layer on a side surface of the first insulating layer and a thickness of the second insulating layer on an upper surface of the first insulating layer is less than a thickness of the first insulating layer.
